(19) United States
(12) Patent Application Publication
(10) Pub. No.: US 2007/0140918 A1
(43) Pub. Date: Jun. 21, 2007

(54) Fluidic separation devices and methods with reduced sample broadening

(76) Inventors: Hongfeng Yin, Cupertino, CA (US); Kevin Killeen, Palo Alto, CA (US); Reid Brennen, San Francisco, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/311,960

(22) Filed: Dec. 19, 2005

(51) Int. Cl. B01L 11/00

(52) U.S. Cl. 422/101; 436/174

(57) ABSTRACT

Fluidic separation devices and methods with reduced sample broadening are provided. A column is located downstream from a holding chamber, and a flow providing means provides fluid flow effective to convey a sample along a flow path that extends from the holding chamber into the separation column. The sample is typically focused in the flow path upstream from the separation column. Optionally, the invention may be employed with electrospray mass spectrometry and in microfluidic applications.

### FIELD OF THE INVENTION

The invention relates generally to fluidic separation devices and methods that provide for reduced sample broadening before a sample is separated into its constituents. In particular, the invention relates to fluidic separation devices and methods that employ a means for focusing the sample before its separation.

### BACKGROUND OF THE INVENTION

Analysis of a fluid sample often involves separating the sample into its constituents. In particular, liquid chromatography (LC) separation typically involves employing a mobile phase to convey a multiconstituent sample past surfaces of a stationary phase, e.g., separation media within a separation column. Due to the interaction between the constituents and the stationary phase surfaces, the constituents are separated according to the speed at which they travel.

LC separation may be carried out using any of a number of techniques. In reverse phase liquid chromatography, for example, hydrophobic surfaces may be used in conjunction with a mobile phase containing a mixture of water and organic solvent to separate the sample constituents according to increasing hydrophobicity. As another example, a mobile phase having a constant composition over time may be used to carry out isocratic LC In contrast, gradient LC employs a mobile phase that exhibits a varying composition during separation.

In general, gradient LC offers a number of advantages over isocratic LC. For example, gradient LC is well suited to separation a wide range of compounds with high speed and resolution. In addition, the composition of the mobile phase may be controllably varied, e.g., to exhibit a concentration gradient, so as to trap certain sample components at an upstream portion of the stationary phase, thereby allowing interfering compounds such as salts to be washed away. As a result, gradient LC allows of injection of large sample volumes without compromising separation efficiency and is well-suited for analysis of low concentration samples.

Microfluidic techniques have been successfully used to carry out gradient LC. For example, an integrated microfluidic LC device is described in U.S. Patent Application Publication No. 2003/0017609 to Yin et al. Such microfluidic devices may be formed as a lab-on-a-chip from a substrate and a cover plate that incorporate a plurality of functionalities e.g., sample injection, separation and flow switching, on a single integrated device. In addition, on-chip gradient generation and fluid introduction technologies have been proposed. For example, U.S. Pat. No. 6,702,256 to Killeen et al. describes a device that employs a slidably switchable valve for controlling microfluidic flow that may be used in an LC application. In addition, techniques for on-chip generation of a mobile-phase gradient using a network of channels are described in U.S. Pat. No. 6,958,119 to Yin et al. Since microfluidic technologies generally involve the use of small volumes of fluids, microfluidic technologies are particularly desirable in applications that involve fluids that are extremely rare and/or expensive.

It is not, however, a trivial matter to scale ordinary LC practices for microfluidic applications. A number of factors may affect LC separation performance, and successful scaling efforts require that these factors be taken into consideration. Exemplary factors that may affect LC separation performance include the stationary phase and/or the mobile phase used, the sample to be separated, how the sample is introduced, the partition of sample constituents between the mobile and stationary phases, the flow rate of the mobile phase relative to the stationary phase, etc.

In particular, sample introduction may pose a problem in scaling LC practices for microfluidic applications. Traditionally, high pressure liquid chromatography (HPLC) involves the use of columns having an internal diameter of about 2 mm to 4.6 mm. The mobile phase flow rate typically ranges from about 0.2 mL/minute to 1 mL/minute. The sample volume is usually between 1 μL and 20 μL. As a result, it typically takes only minutes to load a sample for traditional HPLC separation.

In contrast, microfluidic separation techniques typically use lower mobile phase flow rates. In particular, recent development in microfluidic mass spectrometry (MS) technologies, electrospray MS in particular, has allowed for carrier flow rates on the order of nanoliters per second. As a result, there is increased interest in the art for LC-MS technologies that allows for similar flow rates. For example, microfluidic LC technologies may employ a column having an internal diameter of 75 μm or less along with a LC flow rate of 300 nL/minute or less. For proteomic applications, the sample size is usually about 1 μL to about 20 μL. This creates a problem. At a flow rate of about 300 nL/minute, it would take more than an hour to load a 20 μL sample into the LC column.

In addition, LC performance is directly related to its separation power, N (plate), which can be calculated as:

$$N = {( \frac{Tr}{σ} )}^{2} \qquad ( eq . 1 )$$

where Tr is the retention time of a compound and σ represents total sample band broadening during chromatographic separation process. Total sample band broadening, σ, generally increases with time and represents an aggregate of band broadening contributions from various sources. For example, in systems that exhibit band broadening from contributions of sample injection, column separation and detection, total sample broadening is related to the contributions as follows:
σ²=σᵢₙⱼ²+σ_{col}²+σ_{det}² (eq. 2)
where σᵢₙⱼ, σ_{col}, and σ_{det}, are the band broadening contributions from sample injection, column separation, and detection, respectively. Accordingly, total sample broadening may be generalized as follows:
σ²=Σσᵢ² (eq. 3)
where σᵢ represents the band broadening contribution for source i. It should be evident, then, that separation performance is usually enhanced by reducing residence time and minimizing band broadening contributions from one or more sources, thereby reducing overall band broadening.

One way in which band broadening may be reduced is to speed up the sample loading process. For example, as described in U.S. Patent Application Publication No. 2003/0017609 to Yin et al, microfluidic systems may include a loading chamber sized to hold a predetermined volume of fluid sample. By constructing the loading chamber to allow for slidable and switchable fluid communication, a predetermined volume of fluid sample may be loaded into the chamber or removed therefrom. The loading chamber assists in the accurate and precise handing of a predetermined volume of fluid sample. In addition, the loading chamber may be used to ensure that the fluid sample is introduced as a contiguous plug, so as to enhance separation resolution. Optionally, the loading chamber, as discussed below, may be used as a trapping column.

Nevertheless, there exist opportunities to provide alternatives and improvements to overcome the problems associated with sample broadening in fluidic separation techniques, particularly for microfluidic technologies.

### SUMMARY OF THE INVENTION

In a first aspect, the invention provides a fluidic separation device. The device includes a holding chamber for holding a sample, a separation column for separating the sample, a means for providing fluid flow, and a means for focusing the sample. The column is located downstream from the holding chamber, and the flow providing means provides fluid flow effective to convey the sample along a flow path that extends from the holding chamber into the separation column. The sample-focusing means focuses the sample in the flow path upstream from the separation column. Post-column, a means of detection such as ultraviolet/visible spectroscopy may be employed. Optionally, the invention may be employed in conjunction with electrospray mass spectrometry.

The invention may be used in microfluidic applications. For example, wherein the holding chamber may have a volume no greater than about 20 μL, e.g., has a volume of 0.02 μL to about 5 μL. In addition, microfluidic applications may involve fluid flow rates of no greater than about 10 μL/minute, e.g., no greater than about 1 μL/minute. Optimally, the volumetric flow rate is about 200 nL/minute to about 400 nL/minute.

In certain microfluidic device embodiments of the invention, the device may include a substrate having first and second opposing surfaces and a cover plate having a surface that faces the first surface of the substrate. The separation column may be located between the substrate and cover plates. Optionally, the separation column may be defined in part by portions of the first substrate and cover plate surfaces, e.g., defined by a channel formed in an interior surface of the substrate or cover plate. Further optionally, the holding chamber may be capable of switchable fluid communication with either a sample source or the separation column.

One or more different means for focusing the sample may be used. For example, the sample focusing means may include a material in the holding chamber and/or separation column that renders the holding chamber less sample retentive than the separation column. In addition or in the alternative, a heat source may be used for heating the sample in the holding chamber. In some instances, an inlet may be provided for conveying a fluid into the flow path downstream from the holding chamber and upstream from the separation column.

In another aspect, the invention provides a method for separating a sample into sample constituents. The method typically involves loading a sample into a holding chamber, and providing fluid flow in a manner effective to convey the sample along a flow path that extends from the holding chamber into a separation column. Before the sample travels through the separation column, the sample is focused in the flow path. As a result, the focused sample travels through and is separated by the separation column into sample constituents.

The separation process may be carried out using any of a number of different mobile phases. Typically, a mobile phase comprising water and an organic solvent is used. In some instances, the mobile phase has a constant proportion of water and the organic solvent. Alternatively, the mobile phase may exhibit a concentration gradient of water and the organic solvent. Sometimes, when an mobile phase is initially used to convey the sample from the holding chamber into the flow path, an additional fluid may be introduced into the flow path downstream from the holding chamber and upstream from the separation fluid such that the initial mobile phase and the additional fluid together form an altered mobile phase differing in composition from the initial mobile phase that conveys the sample through the separation column.

### BRIEF DESCRIPTION OF THE DRAWINGS

FIGS. 1A-1C, collectively referred to as FIG. 1, illustrate an exemplary microfluidic device that may incorporate the invention. FIG. 1A illustrates the device in exploded view.

FIGS. 1B and 1C schematically illustrate the microfluidic device in first and second flow path configurations, respectively.

FIG. 2 shows the results of the experimental runs that demonstrate how sample band broadening may be reduced by controlling the relative retention rates of trapping and separation columns.

FIG. 3 shows another exemplary microfluidic device that may incorporate the invention.

### DETAILED DESCRIPTION OF THE INVENTION

Before describing the present invention in detail, it is to be understood that the invention is not limited to specific separation devices or types of analytical instrumentation, as such may vary. It is also to be understood that the terminology used herein is for the purpose of describing particular embodiments only, and is not intended to be limiting.

In addition, as used in this specification and the appended claims, the singular article forms “a,” “an,” and “the” include both singular and plural referents unless the context clearly dictates otherwise. Thus, for example, reference to “a conduit” includes a plurality of conduit as well as a single conduit, reference to “substrate” includes a single substrate as well as a combination of substrates, and the like.

Furthermore, terminology indicative or suggestive of a particular spatial relationship between elements of the invention is to be construed in a relative sense rather an absolute sense unless the context of usage clearly dictates to the contrary. For example, the terms “over” and “on” as used to describe the spatial orientation of a second substrate relative to a first substrate does not necessarily indicate that the second substrate is located above the first substrate. Thus, in a device that includes a second substrate placed over a first substrate, the second substrate may be located above, at the same level as, or below the first substrate depending on the device's orientation. Similarly, an “upper” surface of a substrate may lie above, at the same level as, or below other portions of the substrate depending on the orientation of the substrate.

In this specification and in the claims that follow, reference will be made to a number of terms that shall be defined to have the following meanings, unless the context in which they are employed clearly indicates otherwise:

The term “flow path” as used herein refers to the route or course along which a fluid travels or moves. Flow paths may be formed from one or more fluid-transporting features of a microfluidic device.

The term “fluid-transporting feature” as herein refers to an arrangement of solid bodies or portions thereof that direct fluid flow. As used herein, the term includes, but is not limited to, capillaries, tubing, chambers, reservoirs, conduits and channels. The term “conduit” as used herein refers to a three-dimensional enclosure formed by one or more walls and having an inlet opening and an outlet opening through which fluid may be transported. The term “channel” is used herein to refer to an open groove or a trench in a surface. A channel in combination with a solid piece over the channel forms a conduit.

The term “fluid-tight” is used herein to describe the spatial relationship between two solid surfaces in physical contact such that fluid is prevented from flowing into the interface between the surfaces.

The prefix “micro” refers to items having dimensions on the order of micrometers or having volumes on the order of microliters. Thus, for example, the term “microfluidic device” refers to a device having features of micron or submicron dimensions, and which can be used in any number of processes, chemical or otherwise, involving very small amounts of fluid. Such processes include, but are not limited to, electrophoresis (e.g., capillary electrophoresis or CE), chromatography (e.g., μLC), screening and diagnostics (using, e.g., hybridization or other binding means), and chemical and biochemical synthesis (e.g., DNA amplification as may be conducted using the polymerase chain reaction, or “PCR”) and analysis (e.g., through peptidic digestion). The features of the microfluidic devices are adapted to their particular use. For example, microfluidic devices that are used in separation processes, e.g., CE, may contain microchannels (termed “microconduits” herein when enclosed, i.e., when the second substrate is in place on the microchannel-containing first substrate surface) on the order of 1 μm to 200 μm in diameter, typically 10 μm to 75 μm in diameter, and approximately 0.1 to 50 cm in length. Microfluidic devices that are used in chemical and biochemical synthesis, e.g., DNA amplification, will generally contain reaction zones (termed “reaction chambers” herein when enclosed, i.e., again, when the second substrate is in place on the microchannel-containing first substrate surface) having a volume of about 1 nL to about 100 μL, typically about 10 nL to 20 μL. Other terms containing the prefix “micro,” e.g., “microfeature,” are to be construed in a similar manner.

In general, the invention provides technologies that enhance chromatographic performance by reducing band broadening. For example, a sample plug may be injected into a trapping column located upstream from a LC separation column so that the plug may be separated into its constituents. In some instances, the injection process may contribute to broadening of the sample plug. While the trapping column may serve to focus the sample plug, the sample plug may exhibit further band broadening in dead space between the trapping column and the LC column. The invention may serve to focus or refocus a chromatographic band, e.g., a sample plug, at the head of the LC separation column so that band broadening contributions from the sample injection and/or by trapping column may be reduced or eliminated.

The invention may be provided as a device in some embodiments. The device typically includes a separation column for separating a sample, a means for providing fluid flow and a means for focusing the sample. The column is located downstream from the holding chamber, and the flow providing means provides fluid flow effective to convey the sample along a flow path that extends from the holding chamber into the separation column. The sample-focusing means focuses the sample in the flow path upstream from the separation column. Optionally, the invention may be employed with electrospray mass spectrometry.

The invention may also be provided in some embodiments as a method. The method typically involves loading a sample into a holding chamber and providing fluid flow in a manner effective to convey the sample along a flow path that extends from the holding chamber into a separation column. Again, the sample may be focused in the flow path before the sample travels through and is separated by the separation column into sample constituents.

The invention may be used in microfluidic applications. In microfluidic applications, a holding chamber is typically provided for holding the sample upstream from the separation column. Such a chamber may serve a number of purposes. In some instances, the chamber merely serves to hold a predetermined volume of sample. For example, the holding chamber for use in a microfluidic application may have a volume no greater than about 20 μL, e.g., has a volume of 0.02 μL to about 5 μL. In other instances, the holding chamber may be used to process sample, e.g., trap or focus the sample, and/or serve additional functions.

Microfluidic devices of the invention may include a substrate having first and second opposing surfaces and a cover plate having a surface that faces the first surface of the substrate. The separation column may be located between the substrate and cover plates. Optionally, the separation column may be defined in part by portions of the first substrate and cover plate surfaces, e.g., defined by a channel formed in an interior surface of the substrate or cover plate. Further optionally, the holding chamber may be capable of switchable fluid communication with either a sample source or the separation column.

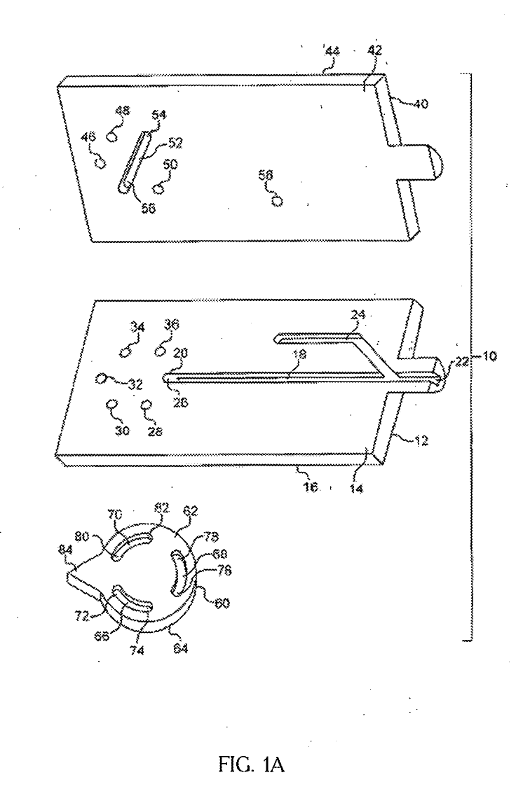

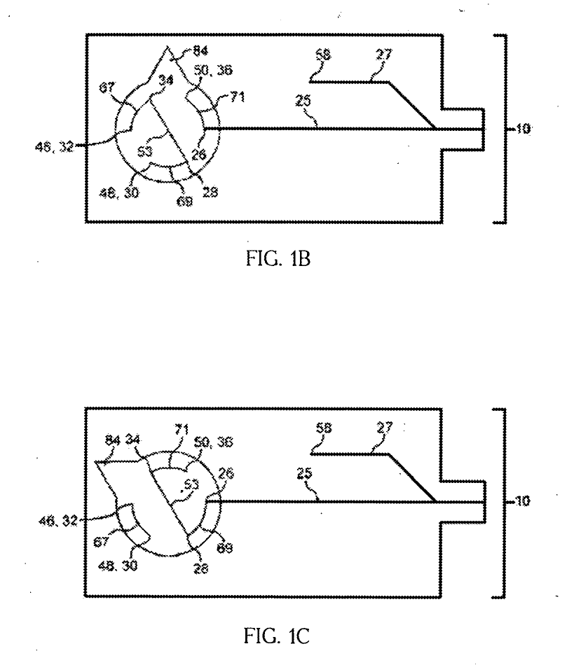

FIG. 1 illustrates an exemplary microfluidic device similar to that described in U.S. Patent Application Publication No. 2003/0017609 to Yin et al. that may benefit from the invention. As with all figures referenced herein, in which like parts are referenced by like numerals, FIG. 1 is not necessarily to scale, and certain dimensions may be exaggerated for clarity of presentation. As illustrated in FIG. 1A, the device 10 includes a substrate 12 comprising first and second substantially planar opposing surfaces indicated at 14 and 16, respectively, and is comprised of a material that is substantially inert with respect to fluids that will be transported through the device. The substrate 12 has a fluid-transporting feature in the form of a separation microchannel 18 in its upper surface 14. The separation microchannel 18 represents a portion of a separation conduit 25 as discussed below. The fluid-transporting feature may be formed through laser ablation or other techniques discussed below or known in the art. It will be readily appreciated that although the separation microchannel 18 has been represented in a generally extended form, separation microchannels for this and other embodiments can have a variety of configurations, such as a straight, serpentine, spiral, or any tortuous path. Further, as described above, the separation microchannel 18 can be formed in a wide variety of channel geometries, including semi-circular, rectangular, rhomboid, and the like, and the channels can be formed in a wide range of aspect ratios. A device may also have a plurality of separation microchannels. The separation microchannel 18 has a sample inlet terminus 20 at a first end and a sample outlet terminus 22 at the opposing end. As shown in FIG. 1, the sample outlet terminus is located at a protrusion of the otherwise rectangular substrate 12 in addition, an optional make-up fluid microchannel 24 is also formed in the first planar surface 14 in fluid communication with the separation microchannel 18, downstream from the sample inlet terminus 20 and upstream from the sample outlet terminus 22. Located at the sample inlet terminus 20 is a cylindrical conduit 26 that extends through surface 16. Five additional cylindrical conduits, 28, 30, 32, 34, 36 also extend through substrate 12 and, in combination with conduit 26, represent the vertices of an equilateral hexagon.

The device 10 also includes a cover plate 40 that is complementarily shaped with respect to the substrate 12 and has first and second substantially planar opposing surfaces indicated at 42 and 44, respectively. The contact surface 42 of the cover plate 40 is capable of interfacing closely with the contact surface 14 of the substrate 12 to achieve fluid-tight contact between the surfaces. The cover plate 40 is substantially immobilized over the substrate contact surface 14, and the cover plate contact surface 42 in combination with the separation microchannel 18 defines a separation conduit 25. Similarly, the cover plate 40, and in combination with the make-up fluid channel 24, defines a make-up fluid conduit 27 for conveying make-up fluid from a make-up fluid source (not shown) to the fluid separation conduit. Because the contact surfaces of the cover plate and the substrate are in fluid-tight contact, the separation conduit and the make-up fluid conduit are fluid tight as well. The cover plate 40 can be formed from any suitable material for forming the substrate 12 as described below. Further, the cover plate 40 can be aligned over the substrate contact surface 14 by any of a number of means known in the art. To ensure that the separation conduit is fluid-tight, pressure-sealing techniques may be employed, e.g., by using external means (such as clips, tension springs or an associated clamp), by using internal means (such as male and female couplings) or by using of chemical means (e.g., adhesive or welding) to urge the pieces together. However, as with all embodiments described herein the pressure sealing techniques may allow the contacts surfaces to remain in fluid-tight contact under an internal device fluid pressure of up to about 100 megapascals, typically about 0.5 to about 40 megapascals.

As shown in FIG. 1A, the cover plate 40 and the substrate 12 may be discrete components. In such a case, microalignment means known to one of ordinary skill in the art may be employed to align the cover plate with the substrate. In some instances, however, the substrate and the cover plate may be formed in a single, solid flexible piece. Devices having a single-piece substrate and cover plate configuration have been described, e.g., in U.S. Pat. Nos. 5,658,413 and 5,882,571, each to Kaltenbach et al.

The cover plate 40 may include a variety of features. As shown, a sample inlet port 46 is provided as a cylindrical conduit extending through the cover plate in a direction orthogonal to the cover plate contact surface 42 to provide communication between surfaces 42 and 44. Although axial symmetry and orthogonality are preferred, the sample inlet port 46 does not have to be axially symmetrical or extend in an orthogonal direction with respect to the cover plate contact surface. The inlet port 46 can be arranged to communicate with the conduit 32 of the substrate 12. As shown, the inlet port 46 has a substantially constant cross-sectional area along its length. The sample inlet port 46 enables passage of fluid from an external source (not shown) through conduit 32 to communicate with switching plate 60 as discussed below. The cross-sectional area of the inlet port should correspond to the cross-sectional area and shape of conduit 32. Similarly, two additional cylindrical conduits, i.e., waste port 48 and mobile phase inlet port 50 are provided fluid communication with conduit 30 and 36, respectively. Further, make-up fluid port 40 is also provided to allow make-up fluid from a make-up fluid source to be introduced into make-up fluid conduit 28.

A linear channel 52 having two termini, indicated at 54 and 56, is located in contact surface 42. The termini 54, 56 fluidly communicate with conduits 34, 28, respectively. The termini 54 and 56 in combination with conduits. 46, 48 and 50 represent five of six vertices of an equilateral hexagon. Accordingly, each of the conduits is located the same distance from the center point of the channel 52. As discussed above, the cover plate 40 is substantially immobilized over the substrate contact surface 14. As a result, substrate surface 14 in combination with channel 52 forms a conduit 53, which serves as a sample-holding chamber. Alternatively, the linear channel 52 may be provided on substrate surface 14. In such a case, termini 54 and 56 would coincide in location with conduits 34 and 28 respectively.

The holding chamber is sized to hold a predetermined volume of fluid sample. In addition, the chamber typically allows for facile, accurate and precise loading and unloading of fluid sample as a contiguous body, so as to enhance separation resolution. Optionally, as discussed below, the holding chamber may serve as a trapping column.

The separation conduit 25 may include or serve as a separation column adapted to separate fluid sample components according to molecular weight, polarity, hydrophobicity or other properties. Such a column may, for example, contain any of a number of known liquid chromatographic packing materials may be included in the separation conduit. Such packing materials typically exhibit a surface area of about 100 m²/g to about 500 m²/g. When ordinary liquid chromatography packing material is slurry packed within the separation conduit, a frit structure, micromachined or otherwise, may be included near or at the sample outlet port. The frit structure serves to ensure that the packing material is not displaced from within the separation conduit when a fluid sample and/or a mobile phase are conveyed through the conduit. In addition, it is preferred that the cross-sectional area of the separation conduit is reduced downstream from the frit structure, particularly if the sample outlet port is a part of an electrospray tip as described, for example, in U.S. patent application Ser. No. 09/711,804.

In addition or in the alternative, the interior surface of the conduit may be chemically, mechanically or otherwise modified using techniques known in the art to carry out separation of the components of a fluid sample according to a selected property. For example, U.S. Pat. No. 6,919,162 to Brennen et al., describes a laser ablated high surface area microchannel; U.S. Pat. No. 5,770,029 to Nelson et al. describes a electrophoretic device that allows for integrated sample enrichment means using a high surface area structure; U.S. Pat. No. 5,334,310 to Frechet et al. describes a microchannel having in-situ generated polymer therein. Thus, the interior surface of the conduit may exhibit surface characteristics such adsorption properties and surface area similar to that associated with packing materials. In any case, typical samples may contain biomolecules such as nucleotidic and/or peptidic moieties.

A switching plate 60 may also be provided. This switching plate 60 is similar to that described in U.S. Pat. No. 6,702,256 to Killeen et al. As shown in FIG. 1A, the switching plate 60 has a substantially planar and circular contact surface 62 and an opposing contact surface 64. As shown, the surfaces 62 and 64 are generally congruent. Three curved fluid-transporting channels, indicated at 66, 68 and 70, are each located on contact surface 62. The fluid-transporting features lie along a circle having a diameter equal to the length of channel 52. Each fluid-transporting channel has two termini: termini 72 and 74 are associated with feature 66, termini 76 and 78 are associated with feature 68, and termini 80 and 82 are associated with feature 70. An optional handle 84 that provides for ease in manipulation of the switching plate 60 extends outwardly from the center of the channels.

The switching plate contact surface 62 may be placed in slidable and fluid-tight contact with substrate surface 16. As a result, the fluid-transporting channels, 66, 68 and 70, in combination with substrate surface 16, form three curved conduits, 67, 69, 71, respectively.

Depending on the relative orientation of the switching plate and the substrate, at least two possible flow paths configurations can be created. As shown in FIG. 1B, the first flow path configuration allows a fluid originating from sample inlet port 46 to travel, in order, through conduit 32, conduit 67, conduit 34, conduit 53, conduit 28, conduit 69, conduit 30 and waste port 48. The first flow path configuration also allows a fluid originating from mobile phase inlet port 50 to travel, in order, through conduit 36, conduit 71, conduit 26 and conduit 25. By rotating the switching plate 60 60° about its center, a second flow path configuration results, as shown in FIG. 1C. The second flow path configuration allows fluid originating from sample inlet port 46 to travel, in order, through conduit 32, conduit 67, conduit 30, and waste port 48. In addition, the second flow path configuration allows fluid originating from conduit 50 to travel, in order, through conduit 36, conduit 70, conduit 34, conduit 53, conduit 28, conduit 69, conduit 26 and separation conduit 25.

In use, the device operates in a manner similar to a simple capillary liquid chromatographic apparatus. The switching plate 60 of the device is arranged to result in a first flow path configuration as discussed above. A fluid-flow providing means in the form of a pump generates a high-pressure gradient to deliver a mobile phase through mobile phase inlet port 50, conduit 36, conduit 71, conduit 26 and conduit 25. In order to control the internal pressure of the device and the flow rate of the mobile phase, a splitter, integrate or otherwise, may be employed to divert a portion of the mobile phase before entry into the conduit 50. In addition, fluid sample is injected into sample inlet port 46 from a sample source. As a result, the fluid sample forms a contiguous body of fluid that flows, through sample inlet port 46 conduit 32, conduit 67, conduit 34, conduit 53, conduit 28, conduit 69, conduit 30 and waste port 48. The sample emerging from conduit 66 may be collected and recycled. Effectively, then, conduit 53 has been loaded with the sample.

By forming a second flow path configuration as discussed above, the conduit 53 is now positioned in the flow path of the mobile phase entering the device through conduit 50. That is, the mobile phase is now pumped through a flow path that travels, in order, through conduit 50, conduit 36, conduit 70, conduit 34, conduit 53, conduit 28, conduit 69, conduit 26 and separation conduit 25. Thus, fluid sample remaining within conduit 53 is also forced through separation conduit 25. It should be evident, then, that by rotating the substrate of the switching assembly, a predetermined volume of fluid sample defined by conduit 53 is controllably introduced from a sample source into the separation conduit 25 of device 10. The sample plug is then separated into sample components according to a component property and emerges from sample outlet port. The outlet may be interfaced with a collector, such as a sample vial, plate or capillary. The collector may serve as a storage device or represent an intermediary to another device that uses and/or analyzes collected fraction. Alternatively, an analytical device may be directly interfaced with the outlet port for fraction analysis.

In any case, the mobile phase may be selected according to the desired sample separation performance. Typically, the mobile phase includes water and an organic solvent. One of ordinary skill in the art will recognize that the organic solvent may be selected according to the sample. Organic solvents may be miscible with water and may include alcohols, ketones, and nitrites, aromatics, etc. In some instances, e.g., for isocratic LC applications, the mobile phase may have a constant proportion of water and the organic solvent. In other instance, e.g., for gradient LC applications, the mobile phase may exhibit a concentration gradient of water and the organic solvent.

Sample band broadening may occur for a number of reasons. For example, band broadening may occur as a result of the construction of a holding chamber. The band broadening contribution from a sample holding chamber is directly correlated to the mobile phase volume the sample analytes are in before they are loaded to the separation column. Therefore, a larger sample holding chamber will contribute more to band broadening than smaller ones. In addition, the holding chamber may not empty directly into the separation column. For example, as shown in FIG. 1C, any fluid sample in conduit 53 must travel through conduits 28, 69, and 26 before reaching the separation column 25. Accordingly, conduits 28, 69 and 26 effectively contain dead volume in which band broadening may occur. When the holding chamber is used as a trapping column that serves to focus the sample analytes, the dead volume in conduits 28, 69, and 26 may serve to defocus the sample, in addition to any band broadening contribution from the trapping column itself.

Thus, as discussed above, the sample may be focused or refocused upstream from the separation column. In general, it is desirable to effect sample focusing or refocusing immediately before the sample is introduced into the separation column. For example, it is typically desirable to effect focusing at or near the head of the separation column. In addition, there are a number of ways sample focusing may be effected. For example, when the holding chamber is used as a trapping column, the trapping column may be larger than the separation column. As a result, the holding chamber may contribute to band broadening to a greater degree that the separation column.

To address the difference in band broadening contributions, one may design and construct a system such that the holding chamber be less sample retentive than the separation column, regardless of their relative sizes. For example, a material may be provided in or omitted from the holding chamber to render the holding chamber less sample retentive than the separation column. In addition or in the alternative, surfaces within the separation column may be modified in such a way so as to render the separation chamber more sample retentive than the trapping column.

The effectiveness of such an approach has been experimentally verified. Three experimental runs were carried out for a sample containing tryptic digest of Bovine Serum Albumin. Extracted ion chromatograms for five selected ions are merged before they are overlaid to similar plot from other runs. The experimental runs were similar in that each involved using a mobile phase exhibiting a gradient of water and organic solvent to convey the sample through a holding chamber followed by a separation column downstream. However, different trapping materials and separation media were used in the holding chamber and the separation column, respectively. In the first run, a polymeric trapping material containing 18 carbons (C18) was used in combination with 3.5 μm, C18 LC separation media In the second run, a C3 trapping material was used in combination with the 3.5 μm, C18 LC separation media. In the third run, the C3 trapping material was used in combination with 2.1 μm, C18 LC separation media.

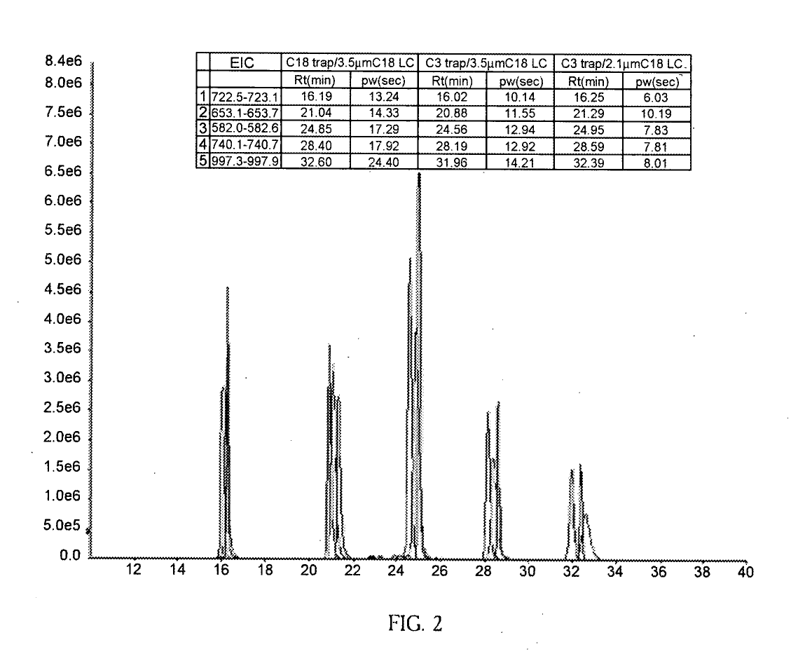

FIG. 2 shows the results of the experimental runs. While each constituent exhibited a substantially identical residence time for the different experimental runs, constituents exhibited different band broadening behaviour. Upon examination of this type of data, one of ordinary skill in the art would be able to optimize a separation system such that the holding chamber is less sample retentive than the LC column. During gradient elution, a sample component may be eluted from the holding chamber at a lower organic solvent content than it would on the separation column. Accordingly, with the proper selection of trapping material and separation media, a LC band of any particular sample constituent may be focused or refocused at the head of a LC separation column.

There are other means for refocusing the sample analyte band at the head of a LC column. In some instances, the trapping column may interact with sample constituents differently at different temperatures than the separation column. Accordingly, a heat source may sometimes be advantageously used to heat the sample in the holding chamber so as to reduce band broadening. For example, in a system employing a mobile phase comprising a mixture of water and organic solvent, the trapping column and the LC column may be packed with the same material. When the trapping column is heated to elevated temperature, sample constituents may elute at a lower organic solvent concentration from the trapping column than the separation column. As a result, sample band broadening may be reduced. One of ordinary skill in the art will recognize that any of a number of heating means may be used to increase the temperature of the trapping column.

In addition, the composition of the mobile phase may serve to refocus the analyte band. Particularly in gradient LC applications that employ a mobile phase comprised of a mixture of water and an organic solvent, changes in composition of the mobile phase may have a dramatic effect on analyte retention. In particular, relative retention properties of the items in the flow path with respect to the sample may be changed. Accordingly, controlled alteration of the composition of the mobile phase at selected locations of the flow path may be employed as a means for focusing or refocusing the sample.

For example, additional fluid may be added to the mobile phase downstream from the trapping column so as to change the composition of the mobile phase conveying the sample after the sample has been processes by the trapping column. This may be done, for example, by including an inlet that fluidly communicates with a source of additional fluid. When water is added to the flow path downstream from the trapping column, the ratio of water to solvent may be increased. For certain samples, such a compositional change in the mobile phase effectively resets or rewinds the time delay associated with different portions of the flow path relative to sample constituents. For example, a sample conveyed by a mobile phase containing a mixture of an organic solvent and water through a trapping column may be associated with a time delay of 38.1 seconds before the sample reaches an LC column. By adding water to the mobile phase in the flow path downstream from the trapping column, the delay time may be reduced to 30 seconds. As a result, the sample may be refocused on the LC column.

Controlled alteration of the composition of the mobile phase may be carried at selected locations of the flow path in other ways as well. For example, when an initial mobile phase comprising water and a first organic solvent is used to convey a sample from the holding chamber, a second organic solvent different from the first may be added downstream from the chamber. Similarly, when an initial mobile phase comprising a mixture of water and an organic solvent is used to convey a sample from the holding chamber, a mixture that contains water and the organic solvent at a different ratio may be added downstream from the chamber. In some instances, it may be possible to selectively extract the mobile phase, or constituents thereof, without extracting the sample constituents from the flow path. Furthermore, it may be useful to introduce a fluid that alters the mobile phase in a manner effective to induce a phase change, e.g., to nucleate a gas or to precipitate a solid from one or more sample constituents.

In short, there are at least three techniques or “degrees of freedom” in which band broadening may be reduced. One involves constructing the holding chamber and the separation column with materials selected that render the holding chamber less sample retentive than the separation column. Another involves selectively changing the temperature of, e.g., heating, the hold chamber or other fluid-transporting features along the flow path. Still another involves selectively altering the composition of the mobile phase in different locations of the flow path. Each of these techniques, and variations thereof, may be used by themselves or in combination.

In any case, an analyzer may be interfaced with any portion of the flow path of the inventive device including in the inlet port. The analyzer may be, for example, a mass spectrometer, in which case the outlet port may be located within or adapted to deliver fluid sample to an ionization chamber. See U.S. patent application Ser. No. 09/711,804 (“A Microdevice Having an Integrated Protruding Electrospray Emitter and a Method for Producing the Microdevice”), inventors Brennen, Yin and Killeen, filed on Nov. 13, 2000. In addition, mass spectrometry technologies are well known in the art and may involve, for example, laser desorption and ionization technologies, whose use in conjunction with devices are described in U.S. Pat. Nos. 5,705,813 and 5,716,825. In the alternative or in addition, the analyzer may be a source of electromagnetic radiation configured to generate electromagnetic radiation of a predetermined wavelength such that the interaction between the radiation and the sample is measured. Depending on the intrinsic properties of the fluid sample and/or any molecular labels used, the radiation may be ultraviolet, visible or infrared radiation.

While the invention is not limited to separation applications involving any particular sample size, it should be evident that the invention is particularly beneficial to microfluidic separation technologies. Band broadening problems are particularly evident in microfluidic applications. In addition, the invention is particularly suited for applications involving low flow rates, because a trapping column is often necessary for large volume sample injection at such low analytical flow rates. For example, the invention may be used successfully in applications that involve a volumetric flow rate of no greater than about 10 μL/minute. Similarly, the invention may be used in applications that involve a volumetric flow rate of no greater than about 1 μL/minute. Applications that involve a volumetric flow rate of no greater than about 200 to about 400 nL/minute may particularly benefit from the invention.

The materials used to form the substrates of the microfluidic devices of the invention as described above are selected with regard to physical and chemical characteristics that are desirable for proper functioning of the microfluidic device. The substrate may be fabricated from a material that enables formation of high definition (or high “resolution”) features, i.e., microchannels, chambers and the like, that are of micron or submicron dimensions. That is, the material must be capable of microfabrication so as to have desired miniaturized surface features.

Preferably, the substrate is capable of being microfabricated in such a manner as to form features in, on and/or through the surface of the substrate. This may be done using materials removal techniques, e.g., dry etching, wet etching, laser etching, laser ablation or the like. However, any material removal technique should be employed with care so as to avoid uncontrolled materials removal. For example careful selection of etch compositions and/or parameters may be required to avoid uncontrolled undercutting, that may accompany etching processes.

Microstructures can also be formed on the surface of a substrate by other techniques. For example, features may be molded and/or embossed on the surface of a substrate. In addition, additive techniques may be used. For example, microstructres may be formed by adding material to a substrate, e.g., using photo-imageable polyimide to form polymer channels on the surface of a glass substrate. Also, all device materials used should be chemically inert and physically stable with respect to any substance with which they come into contact when used to introduce a fluid sample (e.g., with respect to pH, electric fields, etc.).

Suitable materials for forming the present devices include, but are not limited to, polymeric materials, ceramics (including aluminium oxide and the like), glass, metals, composites, and laminates thereof. In general, the terms “metallic,” “ceramic,” “semiconductor” and “polymeric” are used herein in their ordinary sense. For example, the term “metallic” generally describes any of a category of electropositive elements that usually have a shiny surface, are generally good conductors of heat and electricity, and can be formed into thin sheets or wires. Similarly, the term “semiconductor” is used to indicate any of various solid crystalline substances having electrical conductivity greater than insulators but less than good conductors. Exemplary semiconductors include elemental solids such as Si and Ge and compound semiconductors such as GaAs. The term “ceramic” is used to indicate to a hard, brittle, heat-resistant and corrosion-resistant dielectric material made typically made by heating an inorganic compound, e.g., single or mixed metal oxides such as aluminum, zirconium or silicon oxides, nitrides, and carbides, at a high temperature. A ceramic material may be single crystalline, multicrystalline, or, as in the case of glass, amorphous.

Polymeric materials are particularly preferred herein, and will typically be organic polymers that are homopolymers or copolymers, naturally occurring or synthetic, crosslinked or uncrosslinked. Specific polymers of interest include, but are not limited to, polyimides, polycarbonates, polyesters, polyamides, polyethers, polyurethanes, polyfluorocarbons, polystyrenes, polysulfones, poly(acrylonitrile-butadiene-styrene)(ABS), acrylate and acrylic acid polymers such as polymethyl methacrylate, and other substituted and unsubstituted polyolefins, and copolymers thereof. In some instances, halogenated polymers may be used. Exemplary commercially available fluorinated and/or chlorinated polymers include polyvinylchloride, polyvinylfluoride, polyvinylidene fluoride, polyvinylidene chloride, polychorotrifluoroethylene, polytetrafluoroethylene, polyhexafluoropropylene, and copolymers thereof.

Generally, at least one of the substrates comprises a biofouling-resistant polymer when the microfluidic device is employed to transport biological fluids. Polyimide is of particular interest and has proven to be a highly desirable substrate material in a number of contexts. Polyimides are commercially available, e.g., under the tradename Kapton® (DuPont, Wilmington, Del.) and Upilex® (Ube Industries, Ltd., Japan). Polyetheretherketones (PEEK) also exhibit desirable biofouling resistant properties.

The devices of the invention may also be fabricated from a “composite,” i.e., a composition comprised of unlike materials. The composite may be a block composite, e.g., an A-B-A block composite, an A-B-C block composite, or the like. Alternatively, the composite may be a heterogeneous combination of materials, i.e., in which the materials are distinct from separate phases, or a homogeneous combination of unlike materials. As used herein, the term “composite” is used to include a “laminate” composite. A “laminate” refers to a composite material formed from several different bonded layers of identical or different materials. Other preferred composite substrates include polymer laminates, polymer-metal laminates, e.g., polymer coated with copper, a ceramic-in-metal or a polymer-in-metal composite. One preferred composite material is a polyimide laminate formed from a first layer of polyimide such as Kapton®, that has been co-extruded with a second, thin layer of a thermal adhesive form of polyimide known as KJ®, also available from DuPont (Wilmington, Del.).

The embodiments of the invention in the form of microfluidic devices can be fabricated using any convenient method, including, but not limited to, micromolding and casting techniques, embossing methods, surface micro-machining and bulk-micromachining. The latter technique involves formation of microstructures by etching directly into a bulk material, typically using wet chemical etching or reactive ion etching (“RIE”). Surface micro-machining involves fabrication from films deposited on the surface of a substrate.

A preferred technique for preparing the present microfluidic devices is laser ablation. In laser ablation, short pulses of intense ultraviolet light are absorbed in a thin surface layer of material. When laser ablation technique is used, the laser must be selected according to the material to be removed. For example, the energy required to vaporize glass is typically five to ten times higher than that required for organic materials. Laser ablation will typically involve use of a high-energy photon laser such as an excimer laser of the F₂, ArF, KrCl, KrF, or XeCl type or of solid Nd-YAG or Ti:sapphire types. However, other ultraviolet light sources with substantially the same optical wavelengths and energy densities may be used as well. Laser ablation techniques are described, for example, by Znotins et al. (1987) Laser Focus Electro Optics, at pp. 54-70, and in U.S. Pat. Nos. 5,291,226 and 5,305,015 to Schantz et al. Preferred pulse energies for certain materials are greater than about 100 millijoules per square centimeter and pulse durations are shorter than about 1 microsecond. Under these conditions, the intense ultraviolet light photo-dissociates the chemical bonds in the substrate surface. The absorbed ultraviolet energy is concentrated in such a small volume of material that it rapidly heats the dissociated fragments and ejects them away from the substrate surface. Because these processes occur so quickly, there is no time for heat to propagate to the surrounding material. As a result, the surrounding region is not melted or otherwise damaged.

The fabrication technique that is used must provide for features of sufficiently high definition, i.e., microscale components, channels, chambers, etc., such that precise alignment “microalignment” of these features is possible, i.e., the laser-ablated features are precisely and accurately aligned, including, e.g., the alignment of complementary microchannels with each other, projections and mating depressions, grooves and mating ridges, and the like.

To immobilize the substrates of the inventive device relative to each other, fluid-tight pressure sealing techniques may be employed. In some instances, external means may be used to urge the pieces together (such as clips, tension springs or associated clamping apparatus). Internal means such as male and female couplings or chemical means such as welds may be advantageously used as well. Similarly, a seal may be provided between substrates. Any of a number of materials may be used to form the seal. Adhesives such as those in the form of a curable mass, e.g., as a liquid or a gel, may be placed between the substrates and subjected to curing conditions to form an adhesive polymer layer therebetween. Additional adhesives, e.g., pressure-sensitive adhesives or solvent-containing adhesive solutions may be used as well.

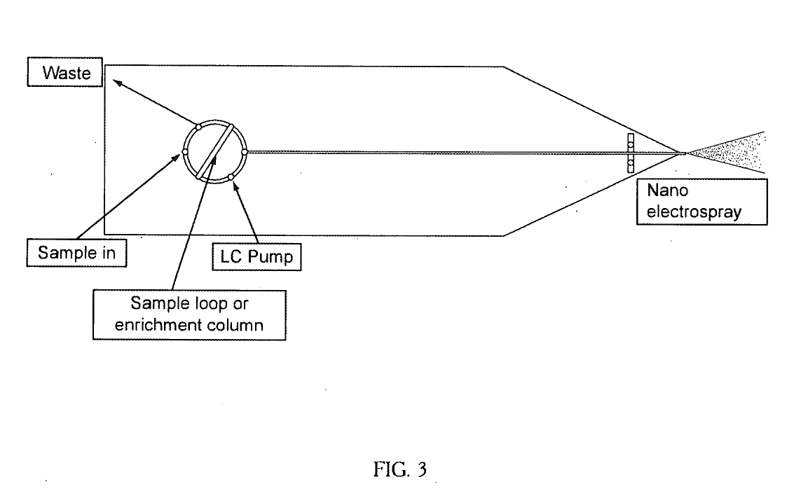

Variations of the present invention will be apparent to those of ordinary skill in the art in view of the disclosure contained herein. For example, the inventive device may be constructed to contain or exclude specific features according to the intended use of the device. When the device is not intended for biofluidic applications, the device may not require a biofouling resistant material. In addition, the invention is scale invariant and may be incorporated for devices of almost any size, microfluidic or otherwise. Furthermore, while the substrate and cover plate shown in FIG. 1 each has a protrusion extending from a main body that is generally rectangular in shape, substrates and cover plates having other geometries may be used as well. For example, FIG. 3 shows the layout for another microfluidic device suitable for HPLC applications. In any case, the invention is not limited to microfluidic applications involving microchannels on a substrate. For example, capillaries, tubing, and other fluid-transporting technologies may be used. Additional variations of the invention may be discovered upon routine experimentation without departing from the spirit of the present invention.

It is to be understood that, while the invention has been described in conjunction with the preferred specific embodiments thereof, the foregoing description merely illustrate and not limit the scope of the invention. Numerous alternatives and equivalents exist which do not depart from the invention set forth above. For example, any particular embodiment of the invention, e.g., those depicted in any drawing herein, may be modified to include or exclude features of other embodiments. Other aspects, advantages, and modifications within the scope of the invention will be apparent to those skilled in the art to which the invention pertains.

All patents and patent applications mentioned herein are hereby incorporated by reference in their entireties to the extent not inconsistent with the description set forth above.

We claim:

1. A fluidic separation device, comprising:
a holding chamber for holding a sample;
a separation column for separating the sample, wherein the column is located downstream from the holding chamber;
a means for providing fluid flow effective to convey the sample along a flow path that extends from the holding chamber into the separation column; and
a means for focusing the sample in the flow path upstream from the separation column.

2. The device of claim 1, wherein the holding chamber has a volume no greater than about 20 μL.

3. The device of claim 2, wherein the sample holding chamber is about 0.02 to about 5 μL in volume.

4. The device of claim 1, wherein the holding chamber is capable of switchable fluid communication with either a sample source or the separation column.

5. The device of claim 1, wherein the means for providing fluid flow is constructed to provide a volumetric flow rate no greater than about 10 μL/minute.

6. The device of claim 5, wherein the volumetric flow rate is no greater than about 1 μL/minute.

7. The device of claim 6, wherein the volumetric flow rate is about 200 to about 300 nL/minute.

8. The device of claim 1, wherein the means for focusing the sample includes a material in the holding chamber and/or separation column that renders the holding chamber less sample retentive than the separation column.

9. The device of claim 1, wherein the means for focusing the sample comprises a heat source for heating the holding chamber.

10. The device of claim 1, wherein the means for focusing the sample comprises an inlet for conveying a fluid into the flow path downstream from the holding chamber and upstream from the separation column.

11. The device of claim 1, further comprising a substrate and a cover plate, wherein the separation column is located between the substrate and the cover plate.

12. The device of claim 11, wherein the separation column is defined at least in part by a channel located on an interior surface of the substrate and/or cover plate.

13. The device of claim 1, wherein the separation column is a microcolumn.

14. The device of claim 1, further comprising an electrospray tip downstream from the separation column.

15. A method for separating a sample into sample constituents, comprising:
(a) loading a sample into a holding chamber;
(b) providing fluid flow in a manner effective to convey the sample along a flow path that extends from the holding chamber into a separation column;
(c) focusing the sample in the flow path before the sample travels through the separation column; and
(d) allowing the focused sample to travel through and be separated by the separation column into sample constituents.

16. The method of claim 15, wherein step (b) is carried out using a mobile phase comprising water and an organic solvent.

17. The method of claim 16, wherein mobile phase has a constant proportion of water and the organic solvent.

18. The method of claim 16, wherein the mobile phase exhibits a concentration gradient of water and the organic solvent.

19. The method of claim 15, wherein step (b) comprises employing an initial mobile phase to convey the sample from the holding chamber along the flow path, and step (c) comprises introducing an additional fluid into the flow path downstream from the holding chamber and upstream from the separation fluid such that initial mobile phase and the additional fluid together form an altered mobile phase that differs in composition from the initial mobile phase that conveys the sample through the separation column.

20. The method of claim 19, wherein the additional fluid contains a higher concentration of water than the initial mobile phase.

21. A microfluidic device, comprising:
a substrate having first and second opposing surfaces;
a cover plate having a surface that faces the first surface of the substrate;
a holding chamber for holding a sample;
a separation column for separating the sample, wherein the column is defined in part by portions of the first substrate and cover plate surfaces is located downstream from the holding chamber; and
a means for providing fluid flow to convey the sample along a flow path that extends from the holding chamber into the separation column; and
a means for focusing the sample in the flow path upstream from the separation column.

22. The device of claim 21, further comprising an electrospray tip that represents an integrated part of the substrate and/or cover plate.
